(19) United States
(12) Patent Application Publication
(10) Pub. No.: US 2010/0206626 A1
(43) Pub. Date: Aug. 19, 2010

(54) PRINTED CIRCUIT BOARD UNIT

(75) Inventors: Yuan-Chi Chang, Taipei City (TW); Wen-Long Lin, Taipei City (TW); Kuo-Liang Tseng, Taipei City (TW)

Correspondence Address: RABIN & Berdo, PC, 1101 14TH STREET, NW, SUITE 500, WASHINGTON, DC, 20005, US

(73) Assignees: SILITEK ELECTRONIC (GUANGZHOU) CO., LTD., Guangzhou (CN); LITE-ON TECHNOLOGY CORPORATION, Taipei City (TW)

(21) Appl. No.: 12/492,608

(22) Filed: Jun. 26, 2009

(30) Foreign Application Priority Data
Feb. 18, 2009 (CN) 200910037333.0

(51) Int. Cl. H05K 1/11

(52) U.S. Cl. 174/262; 174/261

(57) ABSTRACT

A printed circuit board unit includes a substrate and at least one connecting pad on the substrate. The connecting pad is used for electrically connecting to an electronic device by welding method. The connecting pad has at least one venting opening thereon. Therefore, the steam and gas by-produced in reflow soldering process can escape into the environment from the venting opening. Accordingly, the problem of large bubbles formed in the connecting pads is solved.

### BACKGROUND OF THE INVENTION

1. Field of the Invention

The present invention relates to a printed circuit board unit, in particular, to a printed circuit board unit with connecting pads having venting openings.

2. Description of Related Art

Electronic devices such as chips or components are assembled on a printed circuit board (PCB) by a dual in-line package (DIP) method or by surface mount technology (SMT). It is not easy to reduce the size of electronic devices so that the devices occupy the most area of the PCB and the assembling processes are complex in the DIP method. Therefore, SMT is widely used for assembling the components on PCBs today.

The components are assembled on PCB 10′ by a welding method using solder or by reflow soldering using solder paints so as to connect electrically to the pad 12′ on PCB 10′, as shown in FIG. 1.

PCB 10′ includes a substrate 11′, and circuit and pads 12′ arranged on the substrate 11′. PCB 10′ can be classified into FR1 plate, CEM 1 plate or CEM3 plate according to the material of the PCB 10′. These reference codes are clearly defined by NEMA (National Electrical Manufacturers Association) to represent the properties of PCB 10′. The pads 12′ are used for connecting the electronic devices on PCB 10′. In other words, the pins of the electronic devices are fixed to the pad 12′ so that the electronic devices are electrically connected to the circuit on PCB 10′. Therefore, the electronic devices are connected with the circuit electrically so as to achieve the electronic function.

However, when the pins of electronic devices contact the pad 12′ to be welded on the pad 12′, the gas generated in the reflow soldering process is collected inside the pad 12′. Thus, there are bubbles 2′ formed inside the pad 12′.

The generation of bubbles 2′ results from the high temperature of the reflow soldering process. In detail, the pads 12′ of PCB 10′ release gas and moisture at a temperature of 240-260° C. Furthermore, because of the connection of pins and pad 12′, the gas and moisture cannot be escape from the pads 12′. Due to the low fluidity of the soldering paints, the collected gas and moisture inside the pads 12′ expand to form bubbles 2′.

Please refer to FIG. 1A, showing an X-ray inspected image of pad 12′. According to the analysis of the image, the area of bubble 2′ (the brighter portion surrounded by the darker portion) occupies 50% of the area of the pad 12′ (the darker portion in FIG. 1A). The large size of the bubble 2′ affects the reliability and the connection strength. Furthermore, the large bubble 2′ results in the decreased conductivity and the efficiency of signal transmission.

Traditional solder (containing lead) has better fluidity, however this kind of solder is restricted to be used only in certain products for reasons of environment protection. For example, lead-free solder has to be used in PCB manufacture according to RoHS and WEEE regulations.

On the other hand, the soldering paint is applied on the pads 12′ and the usage of soldering paint is great in the structure of traditional pads 12′. Therefore, the cost is increased. Moreover, the soldering paint may flow out of the pads 12′ to cause a short circuit. When larger electronic devices are used, the connection area of the pads 12′ is increased. The above-mentioned problems, such as low fluidity and short circuit will have more effect on the PCB structure.

Consequently, because of the above limitations resulting from the technical design of the prior art, the inventor strives via real world experience and academic research to develop the present invention, which can effectively improve the limitations described above.

### SUMMARY OF THE INVENTION

The present invention provides a printed circuit board unit and a reduced size of the bubbles inside the connecting pad in as SMT process. Therefore, the reliability and the connection force of the welding structure are improved. On the other hand, the required amount of solder is reduced.

To achieve the above-mentioned objectives, the present invention provides a printed circuit board unit, including a substrate, connecting pads and circuit formed on the substrate. Electronic devices are welded on the connecting pads for electrically connecting to the circuit. The connecting pad has at least one venting opening (i.e., a gap) thereon so as to separate the connecting pad into at least two sub pads.

In one embodiment, the venting opening is formed by an etching method.

Because of the venting opening, the gas or moisture generated in the solder reflow step can escape from the gap of the venting opening. Therefore, the gas or moisture will not be collected inside the connecting pad to form bubbles so that the size of bubbles is reduced. The connecting pad can have some venting openings to separate the connecting pad into two or more than two sub pads so that the gas can efficiently escape from the gaps of the venting openings. Thus, the size of the bubbles in the connecting pads is reduced so as to improve the structure strength of the welding structure. On the other hand, the welding area of the connecting pad is decreased because of the gap of the venting opening. Therefore, the required amount of welding material as well as the manufacturing costs is reduced.

In order to further understand the techniques, means and effects the present invention takes for achieving the prescribed objectives, the following detailed descriptions and appended drawings are hereby referred, such that, through which, the purposes, features and aspects of the present invention can be thoroughly and concretely appreciated; however, the appended drawings are merely provided for reference and illustration, without any intention to be used for limiting the present invention.

### BRIEF DESCRIPTION OF THE DRAWINGS

FIG. 1 is a schematic view showing the traditional printed circuit board.

FIG. 1A is an image showing the connecting pads of the traditional printed circuit board inspected by X-ray inspector.

FIG. 2 is a schematic view showing the printed circuit board unit according to the present invention.

FIG. 3 is a schematic view showing a first embodiment of the printed circuit board unit according to the present invention.

FIG. 4 is a schematic view showing a second embodiment of the printed circuit board unit according to the present invention.

FIG. 5 is a schematic view showing a third embodiment of the printed circuit board unit according to the present invention.

FIGS. 6 and 6A are images showing the connecting pads of the printed circuit board unit inspected by X-ray inspector according to the present invention.

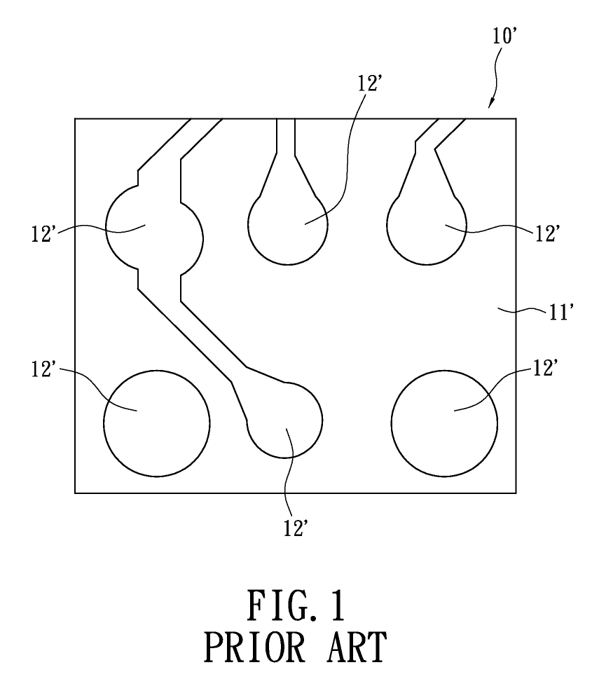

### DETAILED DESCRIPTION OF THE PREFERRED EMBODIMENTS

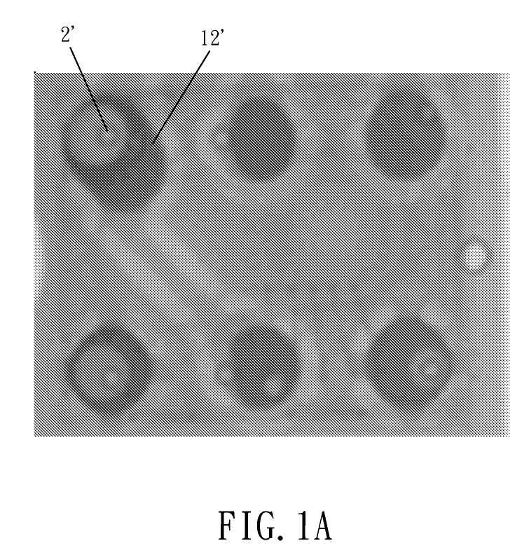

The structure of traditional connecting pad is improved for decreasing the gas or the bubbles collected inside the connecting pad in the reflow soldering step. Therefore, the improvement of the connecting pad is discussed below so as to introduce the structure of the connecting pad of the present invention. Please refer to FIG. 2, the present invention is provided with a printed circuit board unit 10, and the printed circuit board unit 10 has a substrate 11 and at least one connecting pad 12 on the substrate 11. Furthermore, the connecting pad 12 is provided with at least one venting opening 13 thereon. Generally speaking, the printed circuit board unit 10 is supplied by a PCB manufacturer and the substrate 11 of the printed circuit board unit 10 has a copper film thereon. The printed circuit board unit 10 has layout pattern so as to etching the copper film to define the connecting pad 12 and the circuit (not shown). Briefly speaking, the printed circuit board unit 10 has a substrate 11 and at least one connecting pad 12 and circuit formed on the substrate 11. The connecting pad 12 is electrically connected to the circuit and the connecting pad 12 is used for electrically connecting electronic devices thereon. In other words, the connecting pad 12 performs as a connection to weld the electronic devices thereon so that the electronic devices can connect electrically to the circuit on the substrate 11.

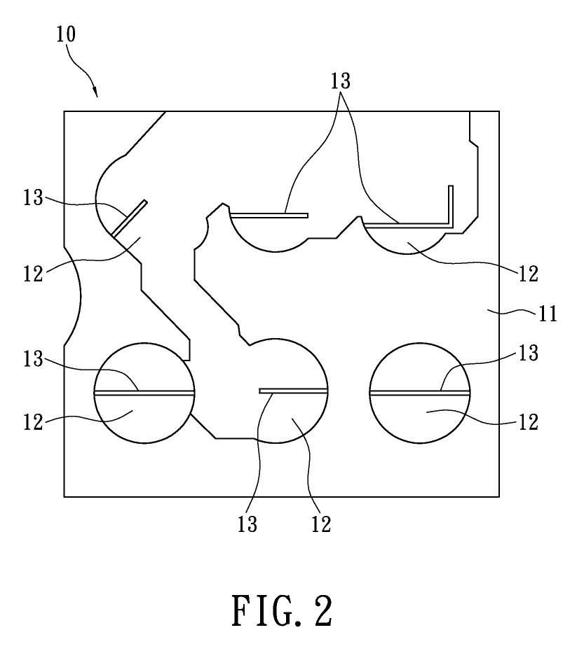

Please refer to FIG. 3, the first embodiment is shown. The connecting pad 12 has one venting opening 13 thereon. In the embodiment, the venting opening 13 is a through channel down to the substrate 11 so that the groove separates the connecting pad 12 into two sub pads 121, 122. The electronic device is weld on the two sub pads 121, 122. The method for manufacturing the venting opening 13 includes the following steps. In a layout step, there is a pattern of the venting opening 13 on the connecting pad 12. Simultaneously in the copper etching step for forming the connecting pad and circuit, the venting opening 13 is formed. Therefore, no extra process is applied in the present invention. After forming the venting opening 13 in the etching step, a step for coating a protection layer 15 adjacent to the connecting pad 12 is provided. In the present embodiment, a kind of paint is applied on the substrate 11 as the protection layer 15. The protection layer 15 has an insulating effect and is used for preventing oxidation of the copper. Because of easy oxidation of copper, the connecting pad 12 is coated with nickel, and the circuit is coated with the protection paint. As shown in FIG. 3, the height of the protection layer 15 is higher than that of the connecting pad 12. However, the method for manufacturing the venting opening 13 is not restricted thereby.

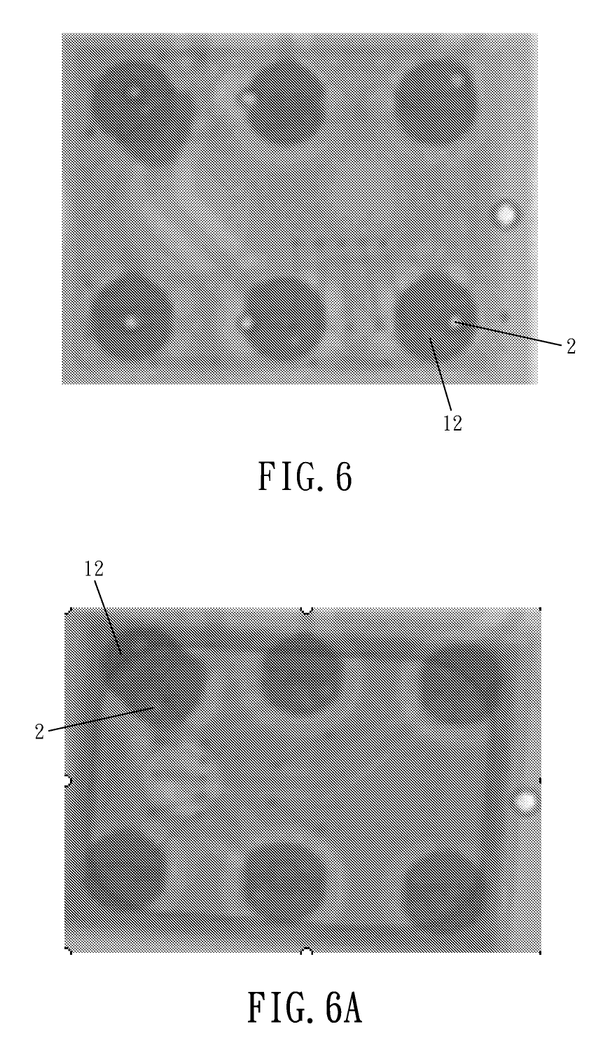

In the processes, the temperature of welding the electronic device on the connecting pad 12 is between 240 to 260° C. The width D of the gap of the venting opening 13 in the connecting pad 12 is 0.15 mm (as shown in FIG. 3) and the venting opening 13 is a through channel down to the substrate 11. The through channel is extending from an upper surface of the connecting pad 12 to a bottom surface of the connecting pad 12. Please refer to FIGS. 6 and 6A, the images by X-ray inspection are shown. Depending on the analysis, the average area of the bubble 2 occupies the total area of the connecting pad 12 in 10%. Accordingly, the gap (i.e., the venting opening) on the connecting pad 12 can decrease the size of the bubble 2 which is generated and collected in the welding process so that the reliability and the connection force are improved. Moreover, the conduction and the efficiency of signal transmission are improved. However, the width D of the venting opening 13 can be adjusted depending on the applications.

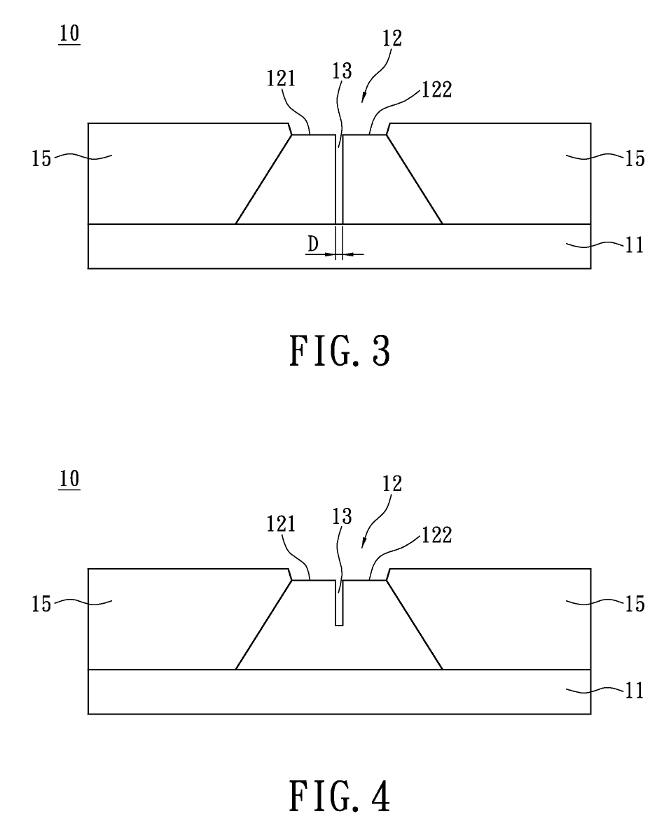

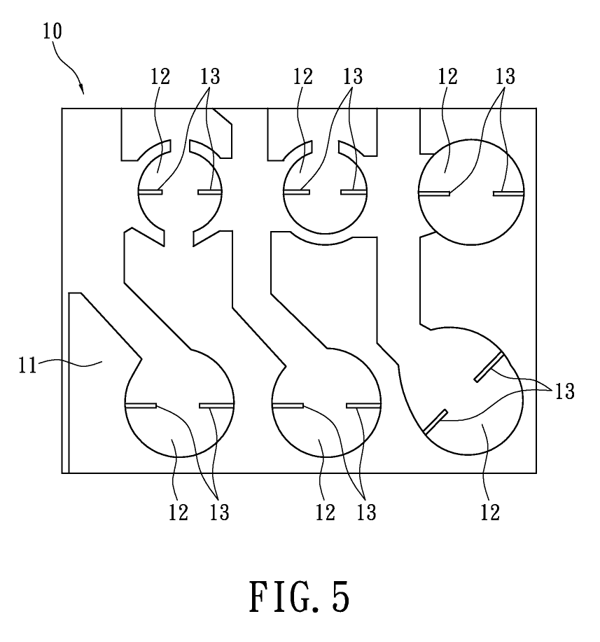

Please refer to FIG. 4, the second embodiment is shown. In the second embodiment, the venting opening 13 is a recess portion extending from an upper surface of the connecting pad 12 inside the connecting pad 12. Therefore, the gas generated during welding can escape through the recess portion so as to reduce the amount of remaining bubbles 2.

Please refer to FIG. 3, a third embodiment of the present invention is shown. In the figure, the layout of the connecting pad 12 and the circuit is shown. In the present embodiment, the connecting pad 12 has two venting openings 13 thereon and the venting openings 13 can be through channel down to the substrate 11 or recess portion some distance into the connecting pad 12. The method for manufacturing the venting openings 13 is similar to the above embodiments.

Because of the separated two or more than two sub pads (i.e., the two sub pads 121, 122 in FIG. 3), the using area of the connecting pad 12 is decreased. Therefore, the required amount of welding material is reduced and the costs decrease. Moreover, the problem of electric shortcuts due to overflowing welding material is solved.

For improving the gas ventilation, there are two or more than two venting openings 13 formed on the connecting pad 12 when a lager electronic device is welded on the printed circuit board unit 10. Therefore, the gas generated in the welding process can escape from the gap of the venting openings 13 so as to reduce the size of the bubbles 2. Furthermore, the required amount of welding material is reduced because the connection area between the electronic device and the connecting pad 12 is decreased.

For example, the venting openings 13 can be put into practice on the manufacturing processes of microphone. The microphone chip has a welding pad corresponding to the connecting pad 12 of the printed circuit board unit 10. After the lead-free soldering paste is applied on the connecting pad 12, the evaporated gas and steam are generated in the solder reflow step. A part of the gas and steam escapes into the environment from the sides of the connecting pad 12. The other part of the gas and steam collected inside the connecting pad 12 escapes into the environment from venting openings 13. Thus, the size of the bubbles 2 in the connecting pad 12 is decreased and the welding strength is improved.

In summary, the present invention has the following advantages.

1. The present invention provides improved welding structure. The connecting pad of the present invention has venting openings thereon so that the ventilation of the connecting pad is improved. The gas or stream generated in the step of welding the electronic device on the printed circuit board unit can escape from the venting openings. Therefore, the size of bubble formed inside the connecting pad is reduced. In other words, the reliability of the welding structure is improved.

2. Because the connecting pad has exposed area (i.e., the venting opening) thereon, the welding area of the connecting pad is decreased. Therefore, the required amount of welding material is reduced so as to decrease costs. Moreover, the problem of electric shortcuts due to overflowing welding material is solved.

The above-mentioned descriptions represent merely the preferred embodiment of the present invention, without any intention to limit the scope of the present invention thereto. Various equivalent changes, alternations or modifications based on the claims of present invention are all consequently viewed as being embraced by the scope of the present invention.

What is claimed is:

1. A printed circuit board unit comprising:
a substrate; and
at least one connecting pad having at least one venting opening on the substrate for electrically connecting an electronic device thereon.

2. The printed circuit board unit according to claim 1, wherein the venting opening is a through channel down to the substrate so that the connecting pad is separated into at least two sub pads by the through channel.

3. The printed circuit board unit according to claim 2, wherein the through channel is extending from an upper surface of the connecting pad to a bottom surface of the connecting pad.

4. The printed circuit board unit according to claim 1, wherein the venting opening is a recess portion some distance into the connecting pad, and the connecting pad is separated into at least two sub pads by the recess portion.

5. The printed circuit board unit according to claim 4, wherein the recess portion is extending from an upper surface of the connecting pad some distance into the connecting pad.

6. The printed circuit board unit according to claim 1, further comprising a protection layer adjacent to the connecting pad.

7. The printed circuit board unit according to claim 1, wherein the venting opening is formed by an etching method.
